(19) United States
(12) Patent Application Publication
(10) Pub. No.: US 2026/0206567 A1
(43) Pub. Date: Jul. 16, 2026

(54) ACCESSING DUMMY WORD LINES USING A THROUGH-SILICON VIA

(71) Applicant: Micron Technology, Inc., Boise, ID (US)

(72) Inventors: Cheng-Hsin Liu, Boise, ID (US); Soeparto Tandjoeng, Boise, ID (US)

(21) Appl. No.: 19/437,828

(22) Filed: Dec. 31, 2025

Related U.S. Application Data
(60) Provisional application No. 63/745,238, filed on Jan. 14, 2025.

(51) Int. Cl. H10W 20/20; G11C 5/06; H10B 80/00; H10W 20/49

(52) U.S. Cl. CPC H10W 20/213; G11C 5/063; H10B 80/00; H10W 20/493

(57) ABSTRACT

Methods, systems, and devices for accessing dummy word lines using a TSV are described. Techniques described herein may enable a memory system to include a via (e.g., a through-silicon via (TSV)) that is exposed through an opening in a substrate on a side of the substrate opposite one or more word lines and “dummy” word lines. As described herein, a via may refer to a contact that may enable biasing of a conductive line and quantifying performance of a conductive line. The TSV may extend to a same height as the substrate or may extend to a height above the substrate. The TSV may be in direct or indirect contact with the dummy word lines (e.g., via a Schottky contact, an oxide fuse, or neither the Schottky contact or oxide fuse). In some examples, the memory system may include a separate TSV coupled with each dummy word line.

### CROSS REFERENCE

The present Application for Patent claims priority to U.S. Patent Application No. 63/745,238 by Liu et al., entitled “ACCESSING DUMMY WORD LINES USING A THROUGH-SILICON VIA,” filed January 14, 2025, which is assigned to the assignee hereof, and which is expressly incorporated by reference in its entirety herein.

### TECHNICAL FIELD

The following relates to one or more systems for memory, including accessing dummy word lines using a through-silicon via.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports accessing dummy word lines using a through-silicon via (TSV) in accordance with examples as disclosed herein.

FIGS. 2A and 2B show examples of architectures that support accessing dummy word lines using a TSV in accordance with examples as disclosed herein.

FIGS. 3A and 3B show examples of architectures that support accessing dummy word lines using a TSV in accordance with examples as disclosed herein.

FIGS. 4A and 4B show examples of architectures that support accessing dummy word lines using a TSV in accordance with examples as disclosed herein.

FIGS. 5A and 5B show examples of architectures that support accessing dummy word lines using a TSV in accordance with examples as disclosed herein.

FIGS. 6A and 6B show examples of architectures that support accessing dummy word lines using a TSV in accordance with examples as disclosed herein.

FIGS. 7A and 7B show examples of architectures that support accessing dummy word lines using a TSV in accordance with examples as disclosed herein.

### DETAILED DESCRIPTION

A memory device (e.g., a testing device) may include one or more conductive lines (e.g., word lines) and one or more “dummy” word lines. The dummy word lines may be used in a testing procedure (e.g., research and development) to test the conductive lines, such as to design guard band devices, to detect shorts, to detect leakage, and the like. The dummy word lines may be coupled with one or more voltage sources (e.g., voltage sources Vnwl or Vccp). In some examples, however, measurements of the dummy word lines may be relatively inaccurate due to error-prone devices used to access the dummy word lines. Additionally, such dummy word lines may not enable a direct quantification of a reliability of the conductive lines.

The memory system may include a via (e.g., a through-silicon via (TSV)) that is exposed through an opening in the substrate on a backside of the wafer (e.g., a side of the substrate opposite the word lines and the dummy word lines). As described herein, a via may refer to a contact that may enable biasing of a conductive line. The TSV may extend to a same height as the substrate or may extend to a height above the substrate. The TSV may be in direct or indirect contact with the dummy word lines (e.g., via a Schottky contact, an oxide fuse, or neither the Schottky contact or oxide fuse). In some examples, the memory system may include a separate TSV coupled with each dummy word line. Accordingly, as part of development of a memory device (e.g., during a research and development stage), the TSVs may enable probing (e.g., backside microprobing, mechanical probing) of the dummy word lines. The backside probing may enable more direct connection between the conductive line (e.g., word line) being measured and the probe. For example, in some cases, when probing is done through the front-side the path between the probe may include one or more redistribution layers and/or one or more other conductive lines in the conductive path between the probe and the conductive line being measured. The more direction connect may allow for detection of shorts of the conductive lines, direct quantification of reliability of the conductive lines, and so on. Such techniques may enable development of relatively more reliable conductive lines, which may increase sustainability and performance of memory systems.

In addition to applicability in memory systems as described herein, techniques for testing dummy word lines using TSVs may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by enabling relatively more accurate testing of word lines for development of memory devices, which may decrease processing or latency times, improve response times, or otherwise improve user experience, among other benefits.

Features of the disclosure are illustrated and described in the context of systems and architectures. Features of the disclosure are further illustrated and described in the context of flowcharts.

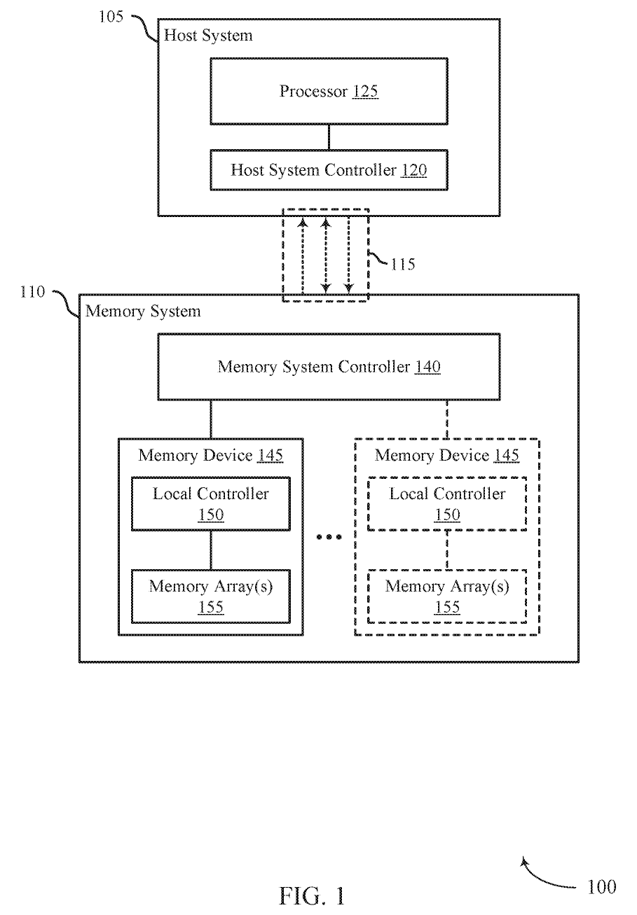

FIG. 1 shows an example of a system 100 that supports accessing dummy word lines using a TSV in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, a memory system 110 may include a via (e.g., a TSV) that is in electrical contact with one or more dummy word lines of the memory system 110. The TSV may accordingly be used to measure a performance of the dummy word lines, which may enable estimation of a performance of word lines of the memory system 110. The TSV may be exposed through an opening in the substrate on a side of the substrate opposite the word lines and the dummy word lines (e.g., the backside of the wafer). The TSV may extend to a same height as the substrate or may extend to a height above the substrate. The TSV may be in direct or indirect contact with the dummy word lines (e.g., via a Schottky contact, an oxide fuse, or neither the Schottky contact or oxide fuse).

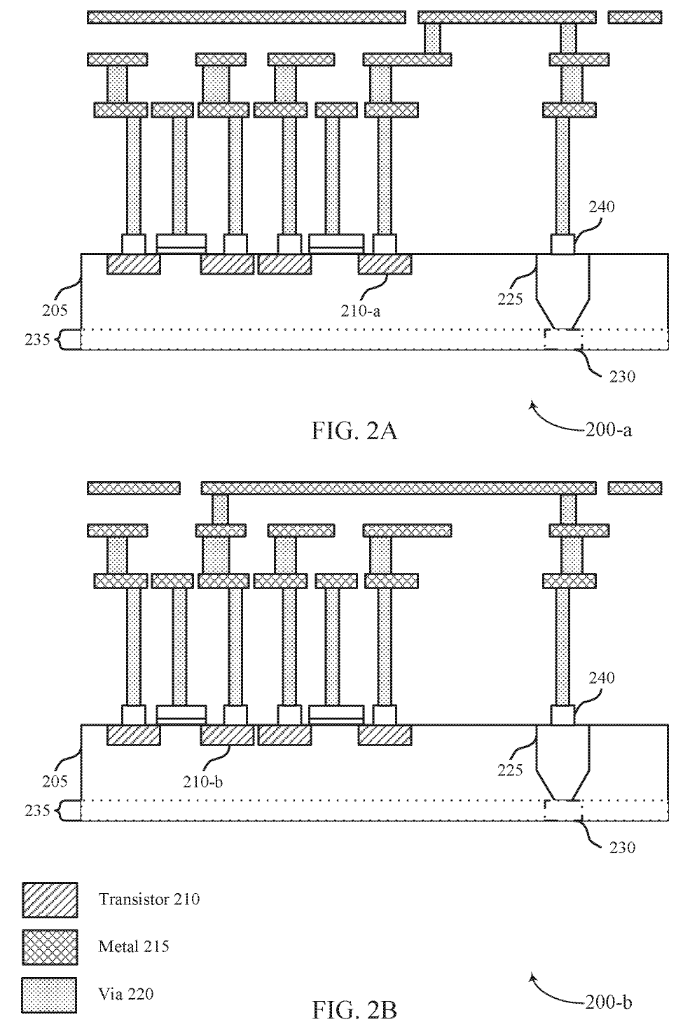

FIGS. 2A and 2B show examples of an architecture 200-a and an architecture 200-b that support accessing dummy word lines using a TSV in accordance with examples as disclosed herein. The architecture 200-a and the architecture 200-b may implement or may be implemented by aspects of the system 100. For example, the architecture 200-a and the architecture 200-b may be implemented by a memory system 110, which may be examples of the corresponding device as described with reference to FIG. 1.

In some examples, a memory device of a memory system may include one or more “dummy” word lines that may enable measurement of timing, reliability, leakage, and shorts of an array of conductive lines (e.g., word lines, such as non-dummy word lines) of the memory device (e.g., without using address topo verification or device edits, which may result in relatively more errors as compared to dummy word line measurements). For example, as part of research and development of the memory system or during wafer-to-wafer bonding, a bias may be applied to one or more dummy word lines to assess a health of the array and to develop guard bands for use in the memory system that may mitigate leakage, prevent marginal or severe shorts and leakages, and the like.

In some examples, the memory device may include a set of dummy word lines (e.g., four dummy word lines) comprised of one or more metals 215 and vias 220 and coupled with a respective transistor 210. For example, the memory system may include a first subset of dummy word lines (e.g., two dummy word lines) that are located relatively closer to one or more word lines (e.g., non-dummy/live/normal word lines) and coupled with a voltage source (e.g., Vccp or Vnwl) via a test mode and a second subset of dummy word lines (e.g., two dummy word lines) that are located relatively further from one or more non-dummy word lines and coupled with Vnwl via a metal 215. However, biasing the dummy word lines via Vnwl and Vccp may not enable direct quantification of word line reliability. For example, there may be intervening conductive lines and/or components that may introduce noise when biasing the dummy word lines via front-side probing.

Accordingly, techniques described herein may enable probing (e.g., backside microprobing, mechanical probing) of the dummy word lines using a TSV 225 that extends through a substrate 205 of the memory system (e.g., a memory device of the memory system including the substrate 205, one or more word lines and dummy word lines comprised of metals 215 and vias 220, transistors 210, and an array of memory cells positioned above a first surface of the substrate). For example, the TSV 225 may be in electrical contact with a target transistor 210-a (e.g., a transistor 210 coupled with a first dummy word line at a near-end of Bank0 or Bank16, as illustrated with reference to the architecture 200-a) or a target transistor 210-b (e.g., a transistor 210 coupled with a second dummy word line at a far-end of Bank15 or Bank31, as illustrated with reference to the architecture 200-b) via one or more metals 215 and vias 220. For example, the memory device may include a separate TSV 225 coupled with each respective dummy word line. To perform the probing, a bias may be applied to the TSV 225 to bias the respective dummy word line.

Accordingly, the dummy word lines may be used to assess a health of the memory device (e.g., to detect reliability, leakage, and shorts of one or more non-dummy word lines). Probing the memory system using the dummy word lines as described herein may be referred to as learning early before probe (LEBP) techniques. Such techniques may repurpose (e.g., recycle) dummy word lines to detect defects in the word lines that may be array edge sensitive (e.g., due to photo or etching processes). In some examples, the TSV 225 may be used to quantify voltage amplitude at a word line source or drain level without incurring interference, which may enable relatively more accurate measurements of the word lines.

In some examples, the memory system may include one or more methods to monitor measurement results of probing using the TSV 225. For example, to enable process monitoring, the memory system may include a probe register or ECAT that may output an indication of defects (e.g., edge defects) related to a short, leakage, and so on of the dummy word lines.

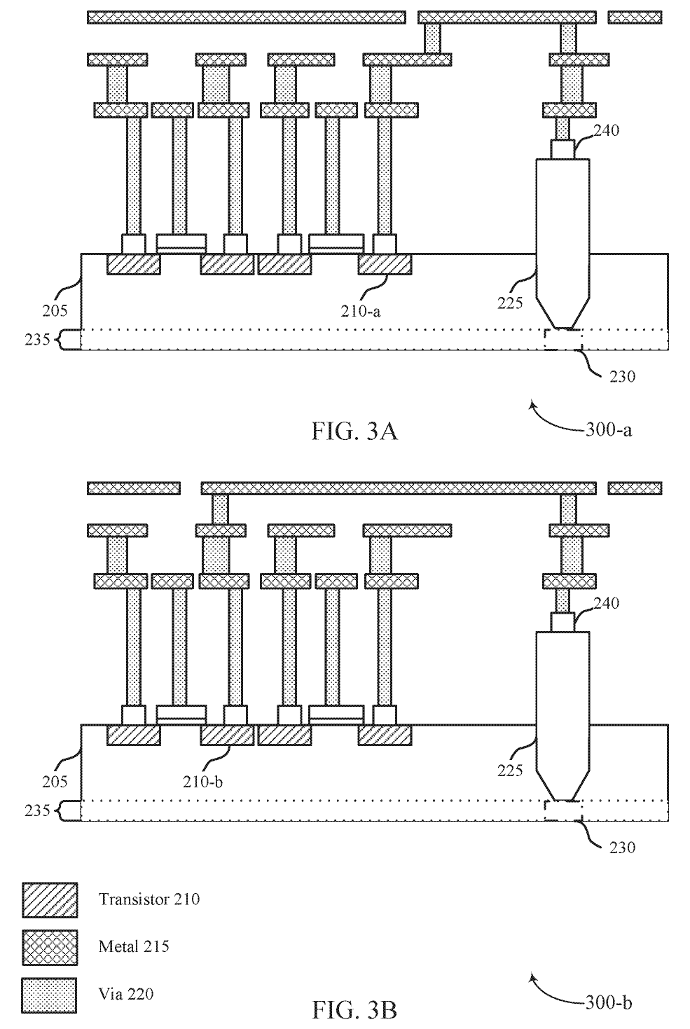

In some examples, as illustrated with reference to FIGS. 2A, 2B, 4A, 4B, 6A, and 6B, a surface of the TSV 225 may be coplanar with a surface of the substrate 205. Such a coplanar TSV 225 may be referred to herein as a via-first TSV 225. In some examples, as illustrated with reference to FIGS. 3A, 3B, 5A, 5B, 7A, and 7B, a surface of the TSV 225 may extend to a height above the surface of the substrate 205. Such a TSV 225 may be referred to herein as a via-middle TSV 225.

To enable the backside probing, the TSV 225 may be exposed through an opening in a second surface (e.g., a bottom surface) of the substrate 205. For example, a portion 235 of the substrate 205 may be removed (e.g., grinded, polished, etched, etc.) to expose the TSV 225. In such examples, the TSV may be coplanar with the second surface of the substrate 205. Additionally, or alternatively, the TSV 225 may be exposed via an indentation (e.g., a hole) in the substrate. For example, the indentation (at area 230) may be drilled through the substrate (e.g., using a focused ion beam (FIB)). In some examples, a micro probe pad (and/or conductive material) may be deposited in contact with the TSV 225, which may enable a connection with the TSV 225.

In some examples, as illustrated with reference to FIGS. 2A, 2B, 3A, and 3B, the TSV 225 may be coupled with the respective word line via one or more contacts 240 (e.g., Schottky contacts). The contacts 240 may reduce a reverse-biased current (e.g., a signal transferred by a metal 215 coupling the dummy word line and the TSV 225).

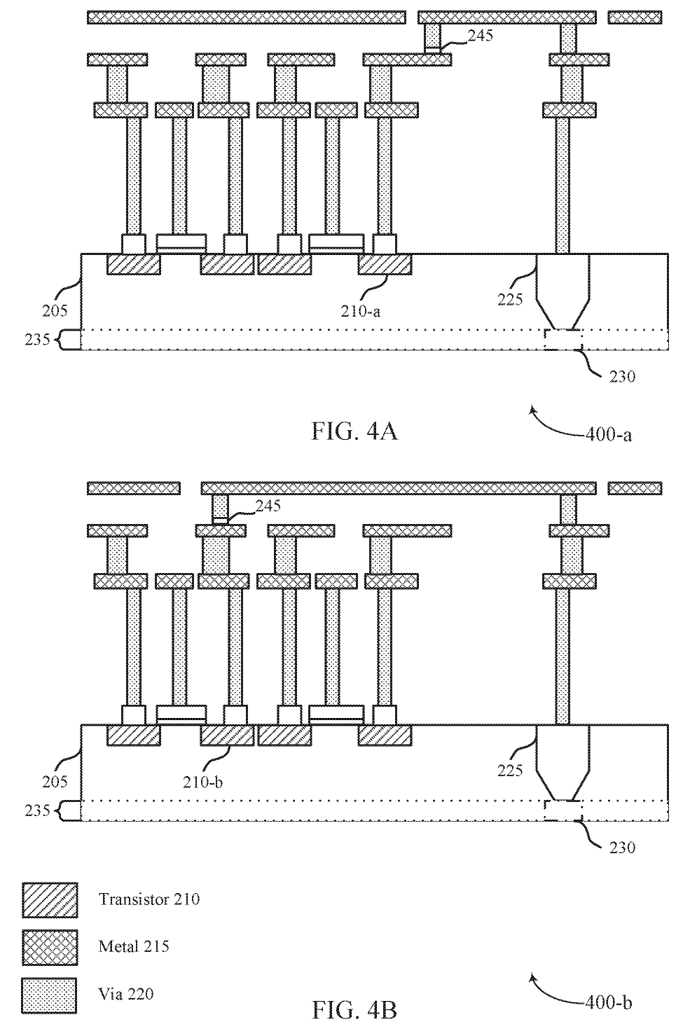

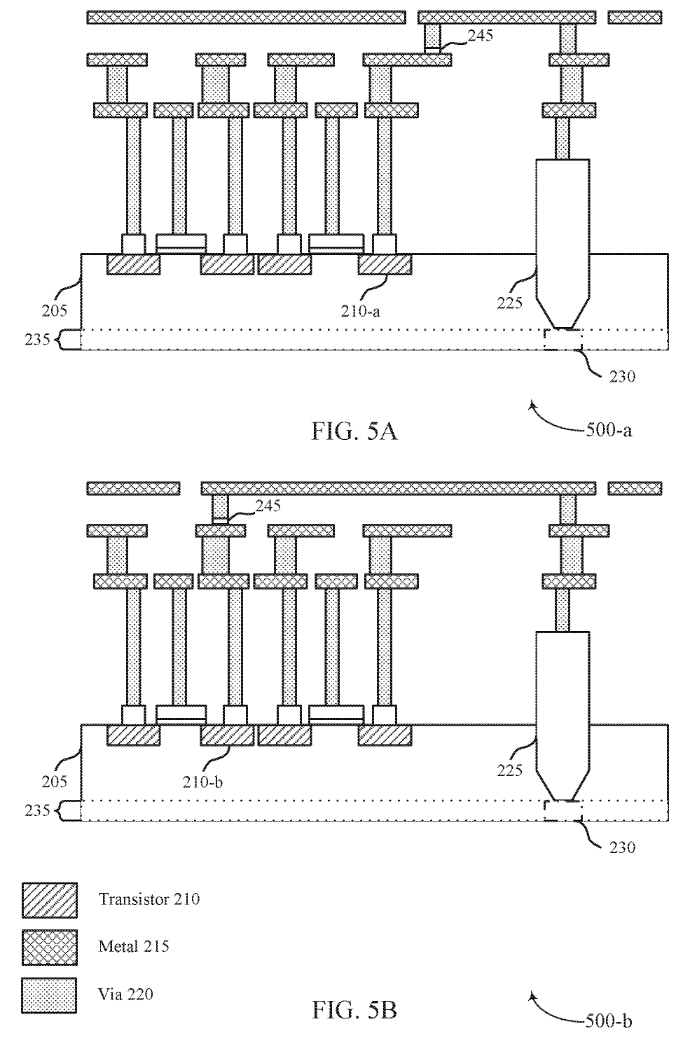

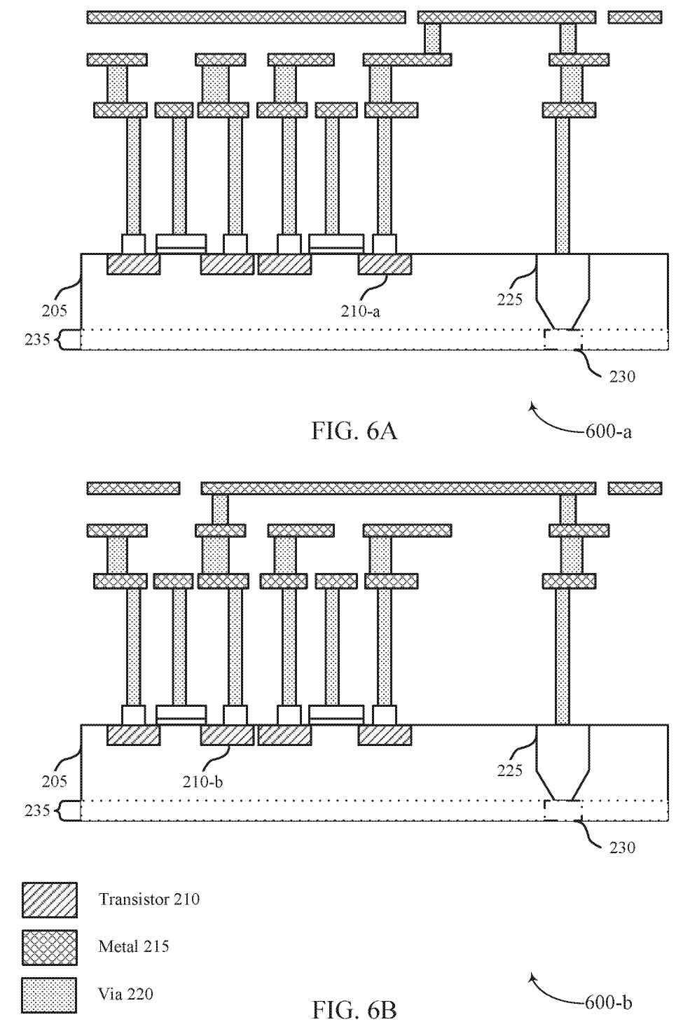

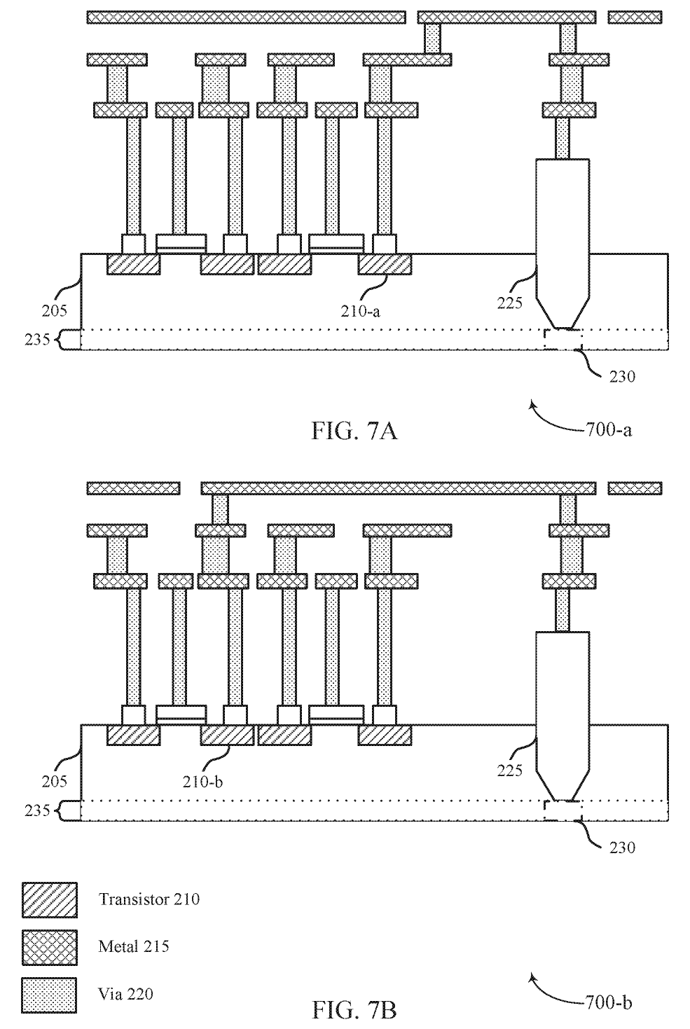

Additionally, or alternatively, as illustrated with reference to FIGS. 4A, 4B, 5A, and 5B the TSV 225 may be coupled with the respective word line via an oxide fuse 245. Additionally, or alternatively, as illustrated with reference to FIGS. 6A, 6B, 7A, and 7B, the TSV 225 may be directly coupled with the respective word line (e.g., without a contact 240 or an oxide fuse 245).

In some examples, techniques described herein may enable backside probing of non-dummy word lines (e.g., instead of or in addition to dummy word lines). In some examples, a non-dummy word line (e.g., a sacrificial word line) tied to the TSV 225 (e.g., in electrical contact with the TSV 225 by way of metals 215 and vias 220) may be disabled for use as a dummy word line.

FIGS. 3A and 3B show examples of an architecture 300-a and an architecture 300-b that support accessing dummy word lines using a TSV in accordance with examples as disclosed herein. The architecture 300-a and the architecture 300-b may implement or may be implemented by aspects of the system 100 or the architectures 200. For example, the architecture 300-a and the architecture 300-b may be implemented by a memory system 110, which may be examples of the corresponding device as described with reference to FIG. 1.

In some examples, as described with reference to FIGS. 2A and 2B, a memory system may include a TSV 225 that extends through a substrate 205 of the memory system (e.g., a memory device of the memory system including the substrate 205, one or more word lines and dummy word lines comprised of metals 215 and vias 220, transistors 210, and an array of memory cells positioned above a first surface of the substrate). For example, the TSV 225 may be in electrical contact with a target transistor 210-a (e.g., a transistor 210 coupled with a first dummy word line at a near-end of Bank0 or Bank16, as illustrated with reference to the architecture 300-a) or a target transistor 210-b (e.g., a transistor 210 coupled with a second dummy word line at a far-end of Bank15 or Bank31, as illustrated with reference to the architecture 300-b) via one or more metals 215 and vias 220. For example, the memory device may include a separate TSV 225 coupled with each respective dummy word line. To perform the backside probing, a bias may be applied to the TSV 225 to bias the respective dummy word line. Accordingly, the dummy word lines may be used to assess a health of the memory device (e.g., to detect reliability, leakage, and shorts of one or more non-dummy word lines).

To enable the backside probing, the TSV 225 may be exposed through an opening in a second surface (e.g., a bottom surface) of the substrate 205. For example, a portion 235 of the substrate 205 may be removed (e.g., grinded, polished, etched, etc.) to expose the TSV 225. In such examples, the TSV may be coplanar with the second surface of the substrate 205. Additionally, or alternatively, the TSV 225 may be exposed via an indentation (e.g., a hole) in the substrate. For example, the indentation (at area 230) may be drilled through the substrate (e.g., using a FIB). In some examples, a micro probe pad (and/or conductive material) may be deposited in contact with the TSV 225, which may enable a connection with the TSV 225.

In some examples, a surface of the TSV 225 may extend to a height above the surface of the substrate 205. Such a TSV 225 may be referred to herein as a via-middle TSV 225. In some examples, the TSV 225 may be coupled with the respective word line via one or more contacts 240 (e.g., Schottky contacts). The contacts 240 may reduce a reverse-biased current (e.g., a signal transferred by a metal 215 coupling the dummy word line and the TSV 225).

FIGS. 4A and 4B show examples of an architecture 400-a and an architecture 400-b that support accessing dummy word lines using a TSV in accordance with examples as disclosed herein. The architecture 400-a and the architecture 400-b may implement or may be implemented by aspects of the system 100, the architectures 200, or the architectures 300. For example, the architecture 400-a and the architecture 400-b may be implemented by a memory system 110, which may be examples of the corresponding device as described with reference to FIG. 1.

In some examples, as described with reference to FIGS. 2A and 2B, a memory system may include a TSV 225 that extends through a substrate 205 of the memory system (e.g., a memory device of the memory system including the substrate 205, one or more word lines and dummy word lines comprised of metals 215 and vias 220, transistors 210, and an array of memory cells positioned above a first surface of the substrate). For example, the TSV 225 may be in electrical contact with a target transistor 210-a (e.g., a transistor 210 coupled with a first dummy word line at a near-end of Bank0 or Bank16, as illustrated with reference to the architecture 400-a) or a target transistor 210-b (e.g., a transistor 210 coupled with a second dummy word line at a far-end of Bank15 or Bank31, as illustrated with reference to the architecture 400-b) via one or more metals 215 and vias 220. For example, the memory device may include a separate TSV 225 coupled with each respective dummy word line. To perform the backside probing, a bias may be applied to the TSV 225 to bias the respective dummy word line. Accordingly, the dummy word lines may be used to assess a health of the memory device (e.g., to detect reliability, leakage, and shorts of one or more non-dummy word lines).

To enable the backside probing, the TSV 225 may be exposed through an opening in a second surface (e.g., a bottom surface) of the substrate 205. For example, a portion 235 of the substrate 205 may be removed (e.g., grinded, polished, etched, etc.) to expose the TSV 225. In such examples, the TSV may be coplanar with the second surface of the substrate 205. Additionally, or alternatively, the TSV 225 may be exposed via an indentation (e.g., a hole) in the substrate. For example, the indentation (at area 230) may be drilled through the substrate (e.g., using a FIB). In some examples, a micro probe pad (and/or conductive material) may be deposited in contact with the TSV 225, which may enable a connection with the TSV 225.

In some examples, a surface of the TSV 225 may be coplanar with a surface of the substrate 205. In some examples, the TSV 225 may be coupled with the respective word line via an oxide fuse 245. For example, the oxide fuse may act as an insulator in an untreated (e.g., default, closed) state. The oxide fuse 245 may act as a conductor in a treated (e.g., open, blown) state, such as after a voltage or laser treatment. Accordingly, the oxide fuse 245 may prevent biasing of the dummy word lines while untreated.

FIGS. 5A and 5B show examples of an architecture 500-a and an architecture 500-b that support accessing dummy word lines using a TSV in accordance with examples as disclosed herein. The architecture 500-a and the architecture 500-b may implement or may be implemented by aspects of the system 100, the architectures 200, the architectures 300, or the architectures 400. For example, the architecture 500-a and the architecture 500-b may be implemented by a memory system 110, which may be examples of the corresponding device as described with reference to FIG. 1.

In some examples, as described with reference to FIGS. 2A and 2B, a memory system may include a TSV 225 that extends through a substrate 205 of the memory system (e.g., a memory device of the memory system including the substrate 205, one or more word lines and dummy word lines comprised of metals 215 and vias 220, transistors 210, and an array of memory cells positioned above a first surface of the substrate). For example, the TSV 225 may be in electrical contact with a target transistor 210-a (e.g., a transistor 210 coupled with a first dummy word line at a near-end of Bank0 or Bank16, as illustrated with reference to the architecture 500-a) or a target transistor 210-b (e.g., a transistor 210 coupled with a second dummy word line at a far-end of Bank15 or Bank31, as illustrated with reference to the architecture 500-b) via one or more metals 215 and vias 220. For example, the memory device may include a separate TSV 225 coupled with each respective dummy word line. To perform the backside probing, a bias may be applied to the TSV 225 to bias the respective dummy word line. Accordingly, the dummy word lines may be used to assess a health of the memory device (e.g., to detect reliability, leakage, and shorts of one or more non-dummy word lines).

To enable the backside probing, the TSV 225 may be exposed through an opening in a second surface (e.g., a bottom surface) of the substrate 205. For example, a portion 235 of the substrate 205 may be removed (e.g., grinded, polished, etched, etc.) to expose the TSV 225. In such examples, the TSV may be coplanar with the second surface of the substrate 205. Additionally, or alternatively, the TSV 225 may be exposed via an indentation (e.g., a hole) in the substrate. For example, the indentation (at area 230) may be drilled through the substrate (e.g., using a FIB). In some examples, a micro probe pad (and/or conductive material) may be deposited in contact with the TSV 225, which may enable a connection with the TSV 225.

In some examples, a surface of the TSV 225 may extend to a height above the surface of the substrate 205. In some examples, the TSV 225 may be coupled with the respective word line via an oxide fuse 245. For example, the oxide fuse may act as an insulator in an untreated (e.g., default, closed) state. The oxide fuse 245 may act as a conductor in a treated (e.g., open, blown) state, such as after a voltage or laser treatment. Accordingly, the oxide fuse 245 may prevent biasing of the dummy word lines while untreated.

FIGS. 6A and 6B show examples of an architecture 600-a and an architecture 600-b that support accessing dummy word lines using a TSV in accordance with examples as disclosed herein. The architecture 600-a and the architecture 600-b may implement or may be implemented by aspects of the system 100, the architectures 200, the architectures 300, the architectures 400, or the architectures 500. For example, the architecture 600-a and the architecture 600-b may be implemented by a memory system 110, which may be examples of the corresponding device as described with reference to FIG. 1.

In some examples, as described with reference to FIGS. 2A and 2B, a memory system may include a TSV 225 that extends through a substrate 205 of the memory system (e.g., a memory device of the memory system including the substrate 205, one or more word lines and dummy word lines comprised of metals 215 and vias 220, transistors 210, and an array of memory cells positioned above a first surface of the substrate). For example, the TSV 225 may be in electrical contact with a target transistor 210-a (e.g., a transistor 210 coupled with a first dummy word line at a near-end of Bank0 or Bank16, as illustrated with reference to the architecture 600-a) or a target transistor 210-b (e.g., a transistor 210 coupled with a second dummy word line at a far-end of Bank15 or Bank31, as illustrated with reference to the architecture 600-b) via one or more metals 215 and vias 220. For example, the memory device may include a separate TSV 225 coupled with each respective dummy word line. To perform the backside probing, a bias may be applied to the TSV 225 to bias the respective dummy word line. Accordingly, the dummy word lines may be used to assess a health of the memory device (e.g., to detect reliability, leakage, and shorts of one or more non-dummy word lines).

To enable the backside probing, the TSV 225 may be exposed through an opening in a second surface (e.g., a bottom surface) of the substrate 205. For example, a portion 235 of the substrate 205 may be removed (e.g., grinded, polished, etched, etc.) to expose the TSV 225. In such examples, the TSV may be coplanar with the second surface of the substrate 205. Additionally, or alternatively, the TSV 225 may be exposed via an indentation (e.g., a hole) in the substrate. For example, the indentation (at area 230) may be drilled through the substrate (e.g., using a focused ion beam (FIB)). In some examples, a micro probe pad (and/or conductive material) may be deposited in contact with the TSV 225, which may enable a connection with the TSV 225.

In some examples, a surface of the TSV 225 may be coplanar with a surface of the substrate 205. In some examples, the TSV 225 may be directly coupled with the respective word line (e.g., without a contact 240 or an oxide fuse 245). Such a direct connection may enable backside probing without treatment of the oxide fuse 245, and may be associated with a relatively smaller production cost as compared to TSVs 225 with a contact 240 or an oxide fuse 245.

FIGS. 7A and 7B show examples of an architecture 700-a and an architecture 700-b that support accessing dummy word lines using a TSV in accordance with examples as disclosed herein. The architecture 700-a and the architecture 700-b may implement or may be implemented by aspects of the system 100, the architectures 200, the architectures 300, the architectures 400, the architectures 500, or the architectures 600. For example, the architecture 700-a and the architecture 700-b may be implemented by a memory system 110, which may be examples of the corresponding device as described with reference to FIG. 1.

In some examples, as described with reference to FIGS. 2A and 2B, a memory system may include a TSV 225 that extends through a substrate 205 of the memory system (e.g., a memory device of the memory system including the substrate 205, one or more word lines and dummy word lines comprised of metals 215 and vias 220, transistors 210, and an array of memory cells positioned above a first surface of the substrate). For example, the TSV 225 may be in electrical contact with a target transistor 210-a (e.g., a transistor 210 coupled with a first dummy word line at a near-end of Bank0 or Bank16, as illustrated with reference to the architecture 700-a) or a target transistor 210-b (e.g., a transistor 210 coupled with a second dummy word line at a far-end of Bank15 or Bank31, as illustrated with reference to the architecture 700-b) via one or more metals 215 and vias 220. For example, the memory device may include a separate TSV 225 coupled with each respective dummy word line. To perform the backside probing, a bias may be applied to the TSV 225 to bias the respective dummy word line. Accordingly, the dummy word lines may be used to assess a health of the memory device (e.g., to detect reliability, leakage, and shorts of one or more non-dummy word lines).

To enable the backside probing, the TSV 225 may be exposed through an opening in a second surface (e.g., a bottom surface) of the substrate 205. For example, a portion 235 of the substrate 205 may be removed (e.g., grinded, polished, etched, etc.) to expose the TSV 225. In such examples, the TSV may be coplanar with the second surface of the substrate 205. Additionally, or alternatively, the TSV 225 may be exposed via an indentation (e.g., a hole) in the substrate. For example, the indentation (at area 230) may be drilled through the substrate (e.g., using a focused ion beam (FIB)). In some examples, a micro probe pad (and/or conductive material) may be deposited in contact with the TSV 225, which may enable a connection with the TSV 225.

In some examples, a surface of the TSV 225 may extend to a height above the surface of the substrate 205. In some examples, the TSV 225 may be directly coupled with the respective word line (e.g., without a contact 240 or an oxide fuse 245). Such a direct connection may enable backside probing without treatment of the oxide fuse 245, and may be associated with a relatively smaller production cost as compared to TSVs 225 with a contact 240 or an oxide fuse 245.

It should be noted that the aspects described herein describe possible implementations, and that the architectures, operations and the steps may be rearranged or otherwise modified and that other implementations are possible. Further, portions from two or more of the architectures and/or methods may be combined.

An apparatus is described. The following provides an overview of aspects of the apparatus as described herein:

Aspect 1: An apparatus, including: a substrate; an array of memory cells positioned above a first surface of the substrate; one or more conductive lines positioned above the first surface of the substrate and coupled with the array of memory cells; and a contact extending through the substrate from the first surface to a second surface opposite the first surface, where the contact is coupled with a conductive line of the one or more conductive lines.

Aspect 2: The apparatus of aspect 1, where the contact is coupled with a conductive line of the one or more conductive lines via an oxide fuse.

Aspect 3: The apparatus of aspect 2, where the oxide fuse includes a conductor between the conductive line and contact based at least in part on the oxide fuse being treated.

Aspect 4: The apparatus of any of aspects 1 through 3, where the contact is directly coupled with a conductive line of the one or more conductive lines via one or more metal components, one or more additional contacts, or some combination thereof.

Aspect 5: The apparatus of aspect 4, where the one or more additional contacts include one or more Schottky contacts.

Aspect 6: The apparatus of any of aspects 1 through 5, where the contact extends to a height that is coplanar with a height of the first surface.

Aspect 7: The apparatus of any of aspects 1 through 6, where the contact extends to a height above a height of the first surface.

Aspect 8: The apparatus of any of aspects 1 through 7, where a bottom surface of the contact is exposed through an opening in the second surface of the substrate.

Aspect 9: The apparatus of aspect 8, where the bottom surface of the contact is coplanar with the second surface of the substrate.

Aspect 10: The apparatus of any of aspects 8 through 9, where the opening through the substrate includes an indentation in the second surface of the substrate.

Aspect 11: The apparatus of any of aspects 1 through 10, where the contact is configured to input or output a voltage bias, signals, or pulses to the conductive line of the one or more conductive lines.

Aspect 12: The apparatus of any of aspects 1 through 11, where the one or more conductive lines include word lines, and where in the conductive line includes a dummy word line.

An apparatus is described. The following provides an overview of aspects of the apparatus as described herein:

Aspect 13: An apparatus, including: a substrate; an array of memory cells positioned above a first surface of the substrate; one or more conductive lines positioned above the first surface of the substrate and coupled with the array of memory cells; and a contact extending through the substrate from the first surface to a second surface opposite the first surface, where the contact is coupled with a conductive line of the one or more conductive lines, and where the contact extends to a height that is coplanar with a height of the first surface.

Aspect 14: The apparatus of aspect 13, where the contact is coupled with a conductive line of the one or more conductive lines via an oxide fuse.

Aspect 15: The apparatus of aspect 14, where the oxide fuse includes a conductor between the conductive line and contact based at least in part on the oxide fuse being treated.

Aspect 16: The apparatus of any of aspects 13 through 15, where the contact is directly coupled with a conductive line of the one or more conductive lines via one or more metal components, one or more additional contacts, or some combination thereof.

Aspect 17: The apparatus of aspect 16, where the one or more additional contacts include one or more Schottky contacts.

An apparatus is described. The following provides an overview of aspects of the apparatus as described herein:

Aspect 18: An apparatus, including: a substrate; an array of memory cells positioned above a first surface of the substrate; one or more conductive lines positioned above the first surface of the substrate and coupled with the array of memory cells; and a contact extending through the substrate from the first surface to a second surface opposite the first surface, where the contact is coupled with a conductive line of the one or more conductive lines, and where the contact extends to a height above a height of the first surface.

Aspect 19: The apparatus of aspect 18, where the contact is coupled with a conductive line of the one or more conductive lines via an oxide fuse.

Aspect 20: The apparatus of aspect 19, where the oxide fuse includes a conductor between the conductive line and contact based at least in part on the oxide fuse being treated.

Aspect 21: The apparatus of any of aspects 18 through 20, where the contact is directly coupled with a conductive line of the one or more conductive lines via one or more metal components, one or more additional contacts, or some combination thereof.

Aspect 22: The apparatus of aspect 21, where the one or more additional contacts include one or more Schottky contacts.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, a wire, a conductive line, a conductive layer, or the like that provides a conductive path between components of a memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a substrate;
an array of memory cells positioned above a first surface of the substrate;
one or more conductive lines positioned above the first surface of the substrate and coupled with the array of memory cells; and
a contact extending through the substrate from the first surface to a second surface opposite the first surface, wherein the contact is coupled with a conductive line of the one or more conductive lines.

2. The apparatus of claim 1, wherein the contact is coupled with a conductive line of the one or more conductive lines via an oxide fuse.

3. The apparatus of claim 2, wherein the oxide fuse comprises a conductor between the conductive line and contact based at least in part on the oxide fuse being treated.

4. The apparatus of claim 1, wherein the contact is directly coupled with a conductive line of the one or more conductive lines via one or more metal components, one or more additional contacts, or some combination thereof.

5. The apparatus of claim 4, wherein the one or more additional contacts comprise one or more Schottky contacts.

6. The apparatus of claim 1, wherein the contact extends to a height that is coplanar with a height of the first surface.

7. The apparatus of claim 1, wherein the contact extends to a height above a height of the first surface.

8. The apparatus of claim 1, wherein a bottom surface of the contact is exposed through an opening in the second surface of the substrate.

9. The apparatus of claim 8, wherein the bottom surface of the contact is coplanar with the second surface of the substrate.

10. The apparatus of claim 8, wherein the opening through the substrate comprises an indentation in the second surface of the substrate.

11. The apparatus of claim 1, wherein the contact is configured to input or output a voltage bias, signals, or pulses to the conductive line of the one or more conductive lines.

12. The apparatus of claim 1, wherein the one or more conductive lines comprise word lines, and where in the conductive line comprises a dummy word line.

13. An apparatus, comprising:
a substrate;
an array of memory cells positioned above a first surface of the substrate;
one or more conductive lines positioned above the first surface of the substrate and coupled with the array of memory cells; and
a contact extending through the substrate from the first surface to a second surface opposite the first surface, wherein the contact is coupled with a conductive line of the one or more conductive lines, and wherein the contact extends to a height that is coplanar with a height of the first surface.

14. The apparatus of claim 13, wherein the contact is coupled with a conductive line of the one or more conductive lines via an oxide fuse.

15. The apparatus of claim 14, wherein the oxide fuse comprises a conductor between the conductive line and contact based at least in part on the oxide fuse being treated.

16. The apparatus of claim 13, wherein the contact is directly coupled with a conductive line of the one or more conductive lines via one or more metal components, one or more additional contacts, or some combination thereof.

17. The apparatus of claim 16, wherein the one or more additional contacts comprise one or more Schottky contacts.

18. An apparatus, comprising:
a substrate;
an array of memory cells positioned above a first surface of the substrate;
one or more conductive lines positioned above the first surface of the substrate and coupled with the array of memory cells; and
a contact extending through the substrate from the first surface to a second surface opposite the first surface, wherein the contact is coupled with a conductive line of the one or more conductive lines, and wherein the contact extends to a height above a height of the first surface.

19. The apparatus of claim 18, wherein the contact is coupled with a conductive line of the one or more conductive lines via an oxide fuse.

20. The apparatus of claim 19, wherein the oxide fuse comprises a conductor between the conductive line and contact based at least in part on the oxide fuse being treated.

21. The apparatus of claim 18, wherein the contact is directly coupled with a conductive line of the one or more conductive lines via one or more metal components, one or more additional contacts, or some combination thereof.

22. The apparatus of claim 21, wherein the one or more additional contacts comprise one or more Schottky contacts.
